(19) United States
(12) Patent Application Publication
(10) Pub. No.: US 2015/0214249 A1
(43) Pub. Date: Jul. 30, 2015

(54) Array Substrate, Display Device and Manufacturing Method

(71) Applicant: BOE TECHNOLOGY GROUP CO., LTD., Beijing (CN)

(72) Inventors: Jun Cheng, Beijing (CN); Jiangbo Chen, Beijing (CN); Xiangyong Kong, Beijing (CN)

(73) Assignee: BOE TECHNOLOGY GROUP CO., LTD., Beijing (CN)

(21) Appl. No.: 14/353,580

(22) PCT Filed: Jun. 20, 2013
(86) PCT No.: PCT/CN2013/077591

§ 371 Date: Apr. 23, 2014

(30) Foreign Application Priority Data
Mar. 28, 2013 (CN) 201310104658.2

(51) Int. Cl. H01L 27/12; H01L 29/24; H01L 27/32; H01L 21/443; H01L 21/4763; H01L 29/786; H01L 29/66

(52) U.S. Cl. CPC H01L 27/1225; H01L 27/1255; H01L 29/7869; H01L 29/24; H01L 27/1259; H01L 29/66969; H01L 21/443; H01L 21/47635; H01L 27/3262

(57) ABSTRACT

An array substrate, a display device and a manufacturing method. The array substrate includes a thin film transistor and a pixel electrode (9). The active layer (4) of the thin film transistor is formed by a first region (401) of the oxide semiconductor layer. The oxide semiconductor layer further includes a second region (402). The pixel electrode (9) and the second region (402) of the oxide semiconductor layer (9) are overlapped so as to form a storage capacitor. The second region (402) of the oxide semiconductor layer (9) constitutes a first electrode plate (402) of the storage capacitor; the pixel electrode (9) corresponding to the second region (402) of the oxide semiconductor layer (4) constitutes a second electrode plate (9) of the storage capacitor; and dielectric layers (7, 8) are disposed between the first electrode plate (402) and the second electrode plate (9).

### TECHNICAL FIELD

Embodiments of the present invention relate to an array substrate, a display device and a manufacturing method.

### BACKGROUND

In recent years, with continuous advancements and improvements of science and technology, display technology has undergone a rapid development. Based on their advantages of high quality image display, self-illumination, fast response speed and wide viewing angle, OLED (Organic Light-Emitting Diodes) displays have occupied a wide market in the display field. More and more OLED display devices have been known by people and applied broadly in their daily life.

However the inventor of the present invention found out that at least the following problems exist for existing array substrates. In prior art, the storage capacitor in an OLED driving circuit is formed by an opaque metal electrode and a pixel electrode. The opaque metal electrode directly influences the magnitude of opening ratio, which in turn increases the current intensity required to emit light in the display device and shortens the service life of the display device.

### SUMMARY

Embodiments of the present invention provide an array substrate, a display device and a manufacturing method for increasing opening ratio of the array substrate by forming first electrode plate of storage capacitor with second region of transparent oxide active layer.

An embodiment of the present invention provides an array substrate comprising a thin film transistor and a pixel electrode,

wherein an active layer of the thin film transistor is formed by a first region of an oxide semiconductor layer,

the oxide semiconductor layer further comprises a second region, the pixel electrode and the second region of the oxide semiconductor layer are overlapped so as to form storage capacitor, the second region of the oxide semiconductor layer constitutes a first electrode plate of the storage capacitor, and the pixel electrode corresponding to the second region of the oxide semiconductor layer constitutes a second electrode plate of the storage capacitor, and

a dielectric layer is disposed between the first electrode plate and the second electrode plate.

In an example, the first electrode plate is formed by performing a hydrogen plasma process for the second region of the oxide semiconductor.

In an example, the first electrode plate has a resistivity smaller than 5×10⁻³

In an example, the second region of the oxide semiconductor layer has a resistivity smaller than that of the first region of the oxide semiconductor layer.

In an example, the first region of the oxide semiconductor layer is isolated from the second region of the oxide semiconductor layer.

In an example, the dielectric layer between the tint electrode plate and the second electrode plate comprises a passivation layer and/or an etch stop layer.

In an example, the material for the oxide semiconductor layer is indium gallium zinc oxide, indium zinc oxide, indium tin oxide or indium gallium tin oxide.

In an example, the etch stop layer and the passivation layer are each of transparent single layer or composite layers structure formed of any one or more selected from oxide of silicon, nitride of silicon, oxide of hafnium, oxynitride of silicon, or oxide of aluminum.

In an example, the dielectric layer between the first electrode plates and the second electrode plates comprises an etch stop layer and a gate insulating layer.

Another embodiment of the present invention provides a display device including the array substrate according to any embodiment of the present invention.

Yet another embodiment of the present invention provides a manufacturing method of an array substrate comprising: forming an oxide semiconductor layer, forming a pixel electrode pattern and forming a dielectric layer between the oxide semiconductor layer and the pixel electrode pattern, wherein the forming the oxide semiconductor layer comprises:

depositing an oxide film and forming a pattern including a first region of the oxide semiconductor layer and a second region of the oxide semiconductor layer by a patterning process, wherein the pixel electrode and the second region of the oxide semiconductor layer are overlapped so as to form a storage capacitor, the second region of the oxide semiconductor layer constitutes a first electrode plate of the storage capacitor, and the pixel electrode corresponding to the second region of the oxide active layer constitutes a second electrode plate of the storage capacitor, and the dielectric layer between the first electrode plates and the second electrode plates constitutes a dielectric of the storage capacitor.

In an example, a pattern including the first electrode plate is formed by performing a hydrogen plasma process for the second region of the oxide semiconductor layer so that the first electrode plate has a resistivity smaller than 5×10⁻³Ω.cm.

In an example, the hydrogen plasma process has a processing time of 150 S, a processing power of 800˜2000 W, and a hydrogen plasma flow rate of 80 SCCM.

In an example, the dielectric layer comprises an etch stop layer and/or a passivation layer.

In the array substrate, the display device and the manufacturing method provided by the present invention, the transparent oxide material is configured to form the first electrode plate of the storage capacitor so that the formed storage capacitor allows the transport of light, hence increasing opening ratio of the array substrate, reducing current intensity required for the display device to emit light and extending service life of the display device.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a driving circuit diagram of an AMOLED array substrate;

FIG. 2 is a schematic layout diagram of an array substrate according to an embodiment of the present invention;

FIG. 3 is a schematic section view showing structures of layers along the A-A direction of the array substrate in FIG. 2;

FIG. 4 is another schematic section view showing structures of layers according to an embodiment of the present invention;

FIG. 5 is a schematic diagram showing a second region of an oxide active layer coated with photoresist according to an embodiment of the present invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

An embodiment of the present invention provides an array substrate, a display device and a manufacturing method, wherein a first electrode plate of a storage capacitor is formed by a second region of the transparent oxide active layer, thus increasing opening ratio of the array substrate.

In figures, thicknesses of respective layers and sizes and shapes of respective areas do not reflect the true scale of an AMOLED (Active Matrix OLED) display, and are only for illustrating of the present invention.

Embodiments of the present invention will be described in detail below with reference to the drawings.

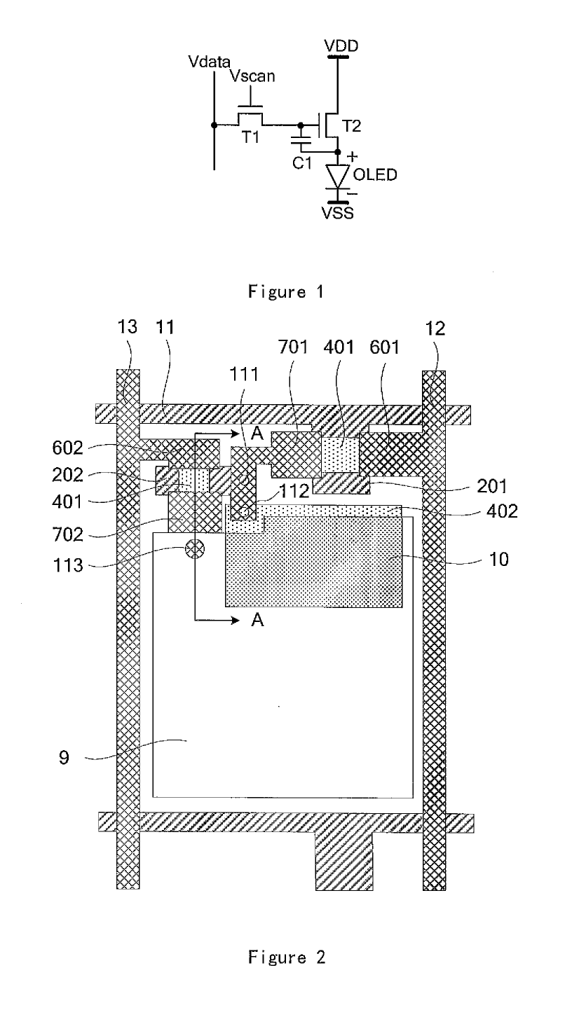

This embodiment provides an array substrate for an AMOLED display. The driving circuit diagram of the array substrate may refer to the circuit diagram of FIG. 1. As shown in FIG. 1, which is a driving circuit diagram of a pixel unit of the AMOLED display, the circuit structure of the pixel unit includes two thin film transistors and one capacitor. A gate line is electrically connected to the gate electrode of the first thin film transistor and a data line is electrically connected to the drain electrode of the first thin film transistor. The electrical signal provided by the gate line turns on/off the first thin film transistor. When the first thin film transistor is turned on, the electrical signal provided by the data line turns on/off the second thin film transistor. When the second thin film transistor is turned on, signal input by power line passes through the second thin film transistor and drives the AMOLED to emit light.

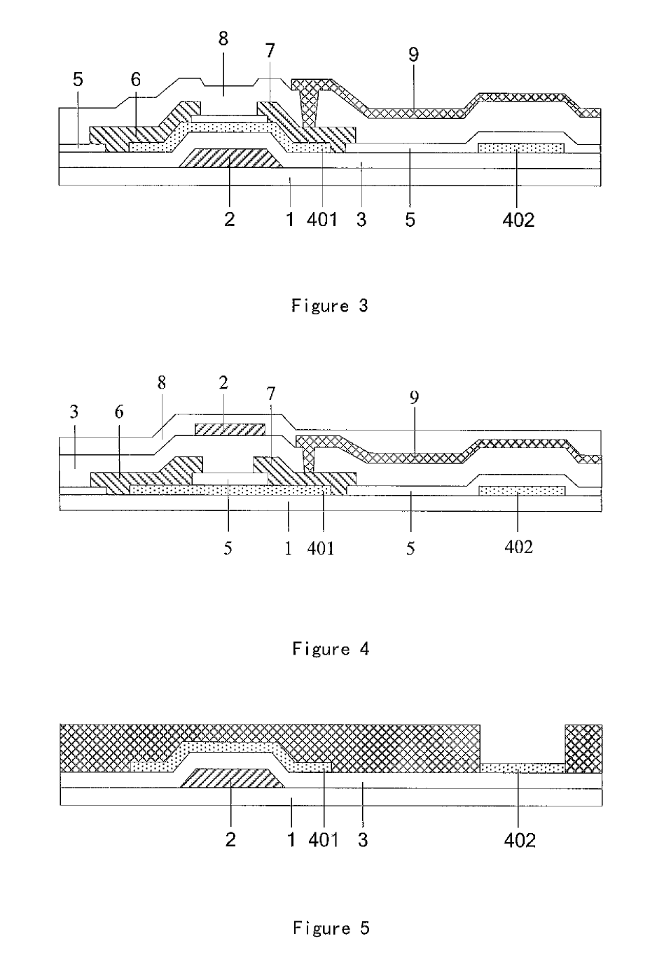

FIG. 2 is a schematic layout diagram of a pixel unit of the array substrate according to the embodiment of the present invention, and FIG. 3 is a schematic section view along the A-A direction of the array substrate in FIG. 2. The sectional view of FIG. 3 shows one thin film transistor according to the embodiment of the present invention. As shown in FIGS. 2 and 3, the main body structure of the thin film transistor in this embodiment includes a gate electrode 2, a gate insulating layer 3, an oxide active layer, an etch stop layer 5, a source electrode 6, a drain electrode 7, a passivation layer 8 and a pixel electrode 9 which are formed on the substrate 1. In particular, the oxide active layer of the thin film transistor includes a first region 401 and a second region 402. For example, the first region 401 of the oxide active layer and the second region 402 of the oxide active layer are formed in the same patterning process. Of course, the above patterns may be formed in different patterning processes if necessary. The pixel electrode 9 and a corresponding part of the second region 402 of the oxide active layer form a storage capacitor. In the storage capacitor, the second region 402 of the oxide active layer constitutes a first electrode plate of the storage capacitor, the pixel electrode 9 corresponding to the second region 402 of the oxide active layer constitutes a second electrode plate of the storage capacitor, layers between the first electrode plate and the second electrode plate constitutes the dielectric of the storage capacitor.

For example, as shown in FIG. 2, the main body structure of the array substrate of the AMOLED of the this embodiment includes a gate line 11, a data line 12, a power line 13, wherein the data line 12 and the power line 13 are perpendicular to the gate line 11. A data line 12, a power line 13, together with two adjacent gate lines 11, define a pixel area. In the pixel area, a first thin film transistor serving as addressing elements (also referred as switch thin film transistor), a second thin film transistor for controlling organic light emitting diodes (also referred as driving thin film transistor) and a pixel electrode 9 are formed. The first thin film transistor is located at the intersection of the gate line 11 and the data line 12, the second thin film transistor is located at the intersection of gate line 11 and power line 13, wherein the first drain electrode 701 of the first thin film transistor is connected with the second gate electrode 202 of the second thin film transistor through the first via 111, or the first drain electrode 701 of the first thin film transistor is disposed at the location of the gate electrode of the second thin film transistor and directly functions as the second gate electrode 202.

As shown in FIG. 2, in the present embodiment, the first gate electrode 201, the second gate electrode 202, and the gate line 11 are disposed onto the substrate 1 and are formed in the same patterning process, wherein the first gate electrode 201 is connected with the gate line 11, the second gate electrode 202 is not connected with the gate line 11, and the first gate electrode 201 are not connected with the second gate electrode 202. The gate insulating layer 3 is formed on the first gate electrode 201, the second gate electrode 202 and the gate line 11 and covers the entire substrate 1. A pattern including the oxide active layer is formed by a second patterning process, wherein the oxide active layer has the first region 401 forming the semiconductor channel of the first thin film transistor and the semiconductor channel of the second thin film transistor which are not connected with each other. The semiconductor channel of the first thin film transistor is disposed over the first gate electrode 201, and the semiconductor channel of the second thin film transistor is disposed over the second gate electrode 202. The etch stop layer 5 is formed on the first region 401 of the oxide active layer and the second region 402 of the oxide active layer and covers the entire substrate 1. Then, the data line 12, the first source electrode 601, the first drain electrode 701 and the power line 13, the second source electrode 602 and the second drain electrode 702 are formed in the same patterning process, wherein one end of the first source electrode 601 is connected to the data line 12, the first source electrode 601 and the first drain electrode 701 are connected through the channel region of the first thin film semiconductor; one end of the second source electrode 602 is connected with the power line 13, the second source electrode 602 and the second drain electrode 702 are connected through the semiconductor channel region of the second thin film semiconductor. A passivation layer 8 is formed on the data line 12, the first source electrode 601, the first drain electrode 701, the power line 13, the second source electrode 602 and the second drain electrode 702 and covers the entire substrate 1. Then a pattern of the pixel electrode 9 is formed by a fourth patterning process.

It should be noted that the source electrode and drain electrodes of the array substrate are denominated in terms of current flow direction. That is, the source electrode and drain electrodes can be varied with different current flow directions. In the present invention, for convenience of description, the one connected with pixel electrode is referred as drain electrode.

It should be further noted that after formation of the etch stop layer 5, a first via hole 111 and a second via hole 112 are formed above the second gate electrode 202 and the second region 402 of the oxide active layer respectively. The first via hole 111 passes through the etch stop layer 5, the gate insulating layer 3 and arrives at the second gate electrode 202. The first drain electrode 701 is connected with the second gate electrode 202 through the first via hole 111. The second via hole 112 passes through the etch stop layer 5 and arrives at the second region 402 of the oxide active layer. The first drain electrode 701 is connected with the second region 402 of the oxide active layer through the second via hole 112. After forming the passivation layer 8, a third via hole 113 is formed above the second drain electrode 702, wherein the third via hole 113 passes through the passivation layer 8 and arrives at the second drain electrode 702. The pixel electrode 9 is connected with the second drain electrode 702 through the third via hole 113.

In the array substrate obtained after the above-mentioned steps, the portion of the second region 402 of the oxide active layer corresponding to pixel electrode 9 is referred to overlapping area 10. As shown in FIG. 2, the overlapping area 10 is the area where the storage capacitor locates. The second region 402 of the oxide active layer constitutes the first electrode plate of the storage capacitor, the pixel electrode 9 corresponding to the second region 402 of the oxide active layer constitutes the second electrode plate of the storage capacitor, and the layers between the first electrode plate and the second electrode plate constitutes the dielectric of the storage capacitor. Since the materials of the storage capacitor are all transparent, the storage capacitor allows the transport of light.

In addition, the gate electrode, the gate line, the source electrode, the drain electrode and the data line can be of a single layer structure or a multilayer stack structure formed of any one or more selected from molybdenum (Mo), molybdenum niobium alloy (MoNb), aluminum (Al), aluminum neodymium alloy (AlNd), titanium (Ti), chromium (Cr) and copper (Cu). The above-mentioned materials contain opaque metal materials, therefore the formed gate electrode, gate line, source electrode, drain electrode and data line are opaque. Preferably, the gate electrode, the gate line, the source electrode, the drain electrode and the data line are of a single layer structure or a multilayer composite membrane structure made of Mo, Al or alloy containing Mo, Al, and has a thickness of 100 nm˜3000 nm respectively.

The gate insulating layer may be a multi-layer composite membrane structure formed of any one or two selected from oxide of silicon (SiOx), nitride of silicon (SiNx), oxide of hafnium (HfOx), nitrogen oxide of silicon (SiON), oxide of aluminum (AlOx). The oxide active layer is formed of film containing elements of In (indium), Ga (gallium), Zn (zinc), O (oxygen), Sn (tin), etc., wherein the film must contain oxygen and other two or more of the elements. For example, the material for oxide active layer may be IGZO (indium gallium zinc oxide), IZO (indium zinc oxide), InSnO (indium tin oxide) and InGaSnO (indium gallium tin oxide).

The etch stop layer and the passivation layer may be of multilayer composite transparent membrane structure formed of any one or two selected from oxide of silicon (SiOx), nitride of silicon (SiNx), oxide of hafnium (HfOx), and oxide of aluminum (AlOx). The etch stop layer and the passivation layer are characterized by low hydrogen content and good surface characteristics.

The pixel electrode may be made of indium tin oxide (ITO), indium zinc oxide (IZO) or other transparent oxides. Taking ITO as an example, it is generally to form an amorphous ITO film by a sputtering method and then crystallize it by an annealing process. Preferably, the layer of pixel electrode has a thickness of 20˜150 nm.

The storage capacitor of the array substrate described in the embodiment of the present invention is of parallel plate capacitor structure. According to, the storage capacitance C satisfies the calculation formula of parallel plate capacitor structure, i.e., C=∈S/4πkd, wherein E is the dielectric constant, S is the corresponding area of the two plates of the storage capacitor, d is the distance between the two plates of the storage capacitor and k is the electrostatic force constant. The corresponding area between the two plates of the storage capacitor depends on the corresponding region between the second region of the oxide active layer and the pixel electrode, and the distance between the two plates depends on the thickness of the layers interposed between the second region of the oxide active layer and the pixel electrode. Therefore, the desired storage capacitance may be obtained by adjusting the corresponding region and the thickness of interposed layers. In addition, it is understood by those skilled in the art that the corresponding region between the second region of the oxide active layer and the pixel electrode is determined by the second region of oxide active layer and the pixel electrode together. Therefore, the corresponding region thus formed may have various possible shapes, such as common shapes of rectangle, square, and triangle or irregular shapes. In addition, the corresponding region thus formed may be formed of plural sub-regions, not limiting to a single region.

It should be noted that although the array substrate of bottom gate structure by the present invention for illustration purpose only, the technology solution mentioned in the present invention is also applicable to an array substrate of top gate structure in which a source electrode and a drain electrode formed on a substrate, and a passivation layer, an oxide active layer, a gate insulating layer and a gate electrode are successively formed thereon; or as shown in FIG. 4, an oxide active layer formed on the substrate, and a passivation layer, a source electrode and a drain electrode, a passivation layer, a gate insulating layer and a gate electrode are successively formed thereon. Compared with the array substrate of bottom gate structure, the array substrates of top gate structure have the same function of the oxide active layer and the same location of the second region of the oxide active layer. Therefore, the array substrates of top gate structure are also applicable to the present technology solution, and the structures of the array substrates of the above two top gate structures and the manufacturing methods thereof will not be described repeatedly.

In addition, it is to be noted that the array substrate of 2T1C pixel structure in which the pixel driving circuit in the array substrate includes only 2 thin film transistors and one capacitor is given by the present invention for illustration purpose only. The oxide active layer includes a first region of the oxide active layer for forming a semiconductor channel region of a thin film transistor and a second region of the oxide active layer for forming a first electrode plate of a storage capacitor so that the formed storage capacitor may allow the transport of light, and finally increasing the opening ratio of the array substrate. It is obvious that the array substrate obtained by the technology solution of the present invention may also have other variations, such as the pixel driving circuit of the array substrate comprising three or four thin film transistors. In comparison to the array substrate of the above embodiments, they have the same function of the oxide active layer and the same location of the second region of the oxide active layer, which will not be repeatedly described herein.

In the array substrates according to embodiments of the present invention, the second region of the transparent oxide active layer are configured to form the first electrode plate of a storage capacitor, pixel electrode corresponding to the second region of transparent oxide active layer are configured to form the second electrode plate of the storage capacitor so that the formed storage capacitor allows the transport of light, hence increasing opening ratio of the array substrate, reducing current intensity required for the display device to emit light and extending service life of the display device.

Preferably, the substrate that has undergone the above-mentioned processes is then subjected to a hydrogen plasma process. The first electrode plate is formed by the second region of the oxide active layer after the hydrogen plasma process such that the first electrode plate has a resistivity smaller than 5×10⁻³Ω.cm and an electrical conductivity closer to metal electrode plate.

Taking an oxide active layer of IGZO (In—Ga—Zn—Ox, indium gallium zinc oxide) as an example, the second region of the oxide active layer is subjected to a hydrogen plasma process implemented by a reactive ion etching device or a plasma enhanced chemical vapor deposition device with a processing time of 150 s, a processing power of 800˜2000 W and a hydrogen flow rate of 80 SCCM (standard-state cubic centimeter per minute). The second region of the oxide active layer after the process has a resistivity of 1×10⁻³Ω.cm while the un-processed first region of the oxide active layer has a resistivity greater than 10⁶Ω.cm. The second region of the oxide active layer exhibiting characteristics of conductor constitutes the first electrode plate of storage capacitor, while the un-processed first region of the oxide active layer exhibiting characteristics of semiconductor constitutes the semiconductor channel region of the thin film transistors.

In particular, as shown in FIG. 5, in the embodiments, the gate electrode 2, the gate line, the gate insulating layer 3 and the oxide active layer are formed on the substrate 1 and patterns of the first region 401 of the oxide active layer and the second region 402 of the oxide active layer are formed by a patterning process. Then, a photoresist is coated onto the substrate and remove the photoresist over the second region 402 of the oxide active layer by a patterning process; a hydrogen plasma process is applied to the substrate thus formed so that the second region 402 of the oxide active layer is processed to exhibit characteristics of conductor. Specifically, after the hydrogen plasma process, the resistivity of second region 402 of the oxide active layer become 1×10⁻³Ω.cm. It is to be noted that the first region of the oxide active layer is not influenced by the hydrogen plasma process, due to the protection of the photoresist. Therefore, after removing the photoresist, the first region of the oxide active layer still have a resistivity greater than 10⁶Ω.cm and constitutes the semiconductor channel regions of the thin film transistors and exhibits characteristics of semiconductor.

Furthermore, the array substrate further includes an etch stop layer and/or a passivation layer, and the layers between the first electrode plate and the second electrode plate include the passivation layer and/or the etch stop layer. The passivation layer and/or the etch stop layer are/is transparent insulating layer(s) and therefore may be configured to form the dielectric of the storage capacitor.

Furthermore, the material for the oxide active layer is indium gallium zinc oxide, indium zinc oxide, indium tin oxide or indium gallium tin oxide.

Furthermore, the etch stop layer and the passivation layer are transparent single layer or composite layers formed of any one or more selected from silicon oxide, silicon nitride, hafnium oxide, silicon nitrogen oxide or aluminum oxide.

In the array substrate according to embodiments of the present invention, the second region 402 of the transparent oxide active layer is configured to form the first electrode plate of the storage capacitor, pixel electrode 9 corresponding to second region 402 of transparent oxide active layer is configured to the form second electrode plate of the storage capacitor so that the formed storage capacitor allows the transport of light, hence increasing opening ratio of the array substrate, reducing current intensity required for the display device to emit light and extending service life of the display device.

Another aspect of the present invention provides a display device including the above array substrate, wherein the structure and operation principle of the array substrate are the same as that described in the above embodiments and will not be repeated herein. In addition, structures of other parts of the display device may refer to the prior art, which will not be described in detail herein.

Hereinbefore, the first region of the oxide active layer actually constitutes the active layer of the thin film transistor, while the second region of the oxide active layer constitutes one of the electrode plates of the storage capacitor. Since the oxide active layer is formed of oxide semiconductor layer, the above first region of the oxide active layer may be referred as the first region of the oxide semiconductor layer, and the above second region of the oxide active layer may be referred as the second region of the oxide semiconductor layer. As described above, it is possible to perform a hydrogen plasma process for the second region of the oxide semiconductor so as to make its resistivity close to that of metal electrode.

In the array substrate of the display device of embodiments of the present invention, the first electrode plate of storage capacitor is made of transparent oxide material so that the formed storage capacitor allows the transport of light, hence increasing opening ratio of the array substrate, reducing current intensity required for the display device to emit light and extending service life of the display device.

Yet another aspect of the present invention provides a manufacturing method of an array substrate including steps of:

Step S1, depositing a gate metal film on a substrate and forming a pattern including gate electrode and gate lines by a patterning process;

Step S2, forming a gate insulating layer on the substrate after the aforementioned step;

Step S3, depositing an oxide active layer film on the substrate after the aforementioned steps and forming a pattern including first region of the oxide active layer and second region of the oxide active layer by a patterning process;

Step S4, forming an etch stop layer film on the substrate after the aforementioned steps, forming a pattern including an etch stop layer, first via hole of the etch stop layer located at the gate electrode and second via hole of the etch stop layer located at the second region of the oxide active layer by a patterning process, wherein the first via hole of the etch stop layer penetrates the etch stop layer and the gate insulating layer to reach and expose the gate electrode; the second via hole of the etch stop layer penetrates the etch stop layer to reach and expose the second region of the oxide active layer;

Step S5, depositing a source and drain metal film on the substrate after the aforementioned steps, and forming a pattern including source electrode, drain electrode, a data line and a power line by a patterning process;

Step S6, depositing a passivation layer film on the substrate after the aforementioned steps, and forming a pattern including the passivation layer and passivation layer via hole located at the drain electrode by a patterning process, wherein the passivation layer via hole penetrates the passivation layer to reach and expose the drain electrode.

Step S7, depositing a transparent conductive film on the substrate after the aforementioned steps, and forming a pattern including pixel electrode by a patterning process, wherein the pixel electrode is connected with the drain electrode through the via hole.

In the manufacturing method of the array substrate according to the embodiment of the present invention, the second region of transparent oxide active layer is configured to constitute the first electrode plate of the storage capacitor; the pixel electrode corresponding to second region of the transparent oxide active layer forms the second electrode plate of storage capacitor; and the layers between first and second electrode plates form the dielectric of the storage capacitor, so that the formed storage capacitor allows the transport of light, hence increasing opening ratio of the array substrate, reducing current intensity required for the display device to emit light and extending service life of the display device.

Preferably, the pattern including the first electrode plate is formed by performing a hydrogen plasma process for the second region of the oxide active layer so that the first electrode plate have a resistivity smaller than 5×10⁻³Ω.cm.

The manufacturing method of the array substrate according to a preferable embodiment of the present invention includes:

Step S101, depositing a gate metal film on a substrate with a magnetron sputtering or thermal evaporation method and forming a pattern including a first gate electrode, a second gate electrode and gate lines with a common patterning process;

Step S102, coating a gate insulating layer with a spin coating method;

Step S103, depositing an oxide active layer film with a plasma enhanced chemical vapor deposition method and forming a pattern including a first region of the oxide active layer and a second region of the oxide active layer with a patterning process;

Step S104, coating a layer of photoresist on the oxide active layer film and forming a photoresist pattern exposing the second region of the oxide active layer with a patterning process; performing a hydrogen plasma processing for the substrate after the above steps with a specific processing time of 150 s, a processing power of 800˜2000 W, and a hydrogen flow rate of 80 SCCM, and after that stripping the photoresist on the substrate;

Step S105, depositing an etch stop layer film with a plasma enhanced chemical vapor deposition method, and forming a pattern including a first via hole located at the second gate electrode and a second via hole located at the second region of the oxide active layer by a patterning process with a common mask, wherein the first via hole penetrates the etch stop layer and the gate insulating layer to reach the second gate electrode; the second via hole penetrates the etch stop layer to reach the second region of the oxide active layer;

Step S106, depositing a source and drain metal film with a magnetron sputtering or thermal evaporation method, and forming a pattern including first and second source electrodes, and first and second drain electrodes, a data line, and a power line with a patterning process; wherein the first drain electrode are connected with the second gate electrode and the second region of the oxide active layer through the first via hole and the second via hole respectively;

Step S107, depositing a passivation layer film with a plasma enhanced chemical vapor deposition method and forming a pattern including third via hole located at the second drain electrode by a patterning process with a common mask, wherein the third via hole penetrates the passivation layer to reach the second drain electrode;

Step S108, depositing a transparent conductive film, and forming a pattern of pixel electrode by a patterning process, wherein the pixel electrode is connected with the second drain electrode through the third via hole.

In the technology solution of the present embodiment, the second region of the oxide active layer is treated by a hydrogen plasma process after the formation of the oxide active layer. The manufacturing process has been described in detail in the aforementioned technology solution and is not repeated herein.

Furthermore, the hydrogen plasma process has a processing time of 150 s, a processing power of 800˜2000 W, and a hydrogen plasma flow rate of 80 SCCM.

Furthermore, the array substrate further includes an etch stop layer and/or a passivation layer, and the layers between the first electrode plate and the second electrode plate include the passivation layer and/or the etch stop layer.

In the manufacturing method of the array substrate according to embodiments of the present invention, the second region of the transparent oxide active layer are configured to constitute the first electrode plate of the storage capacitor, the pixel electrode corresponding to the second region of the transparent oxide active layer forms the second electrode plate of storage capacitor such that the formed storage capacitor allows the transport of light, hence increasing opening ratio of the array substrate, reducing current intensity required for the display device to emit light and extending service life of the display device.

What are described above is related to the illustrative embodiments of the disclosure only and not limitative to the scope of the disclosure; the scopes of the disclosure are defined by the accompanying claims.

1. An array substrate comprising a thin film transistor and a pixel electrode,
wherein an active layer of the thin film transistor is formed by a first region of an oxide semiconductor layer,
the oxide semiconductor layer further comprises a second region, the pixel electrode and the second region of the oxide semiconductor layer are overlapped so as to form a storage capacitor, the second region of the oxide semiconductor layer constitutes a first electrode plate of the storage capacitor, the pixel electrode corresponding to the second region of the oxide semiconductor layer constitutes a second electrode plate of the storage capacitor, and
a dielectric layer is disposed between the first electrode plate and the second electrode plate.

2. The array substrate of claim 1, wherein
the first electrode plate is formed by performing a hydrogen plasma process for the second region of the oxide semiconductor.

3. The array substrate of claim 1, wherein the first electrode plate has a resistivity smaller than 5×10⁻³Ω.cm.

4. The array substrate of claim 1, wherein the second region of the oxide semiconductor layer has a resistivity smaller than that of the first region of the oxide semiconductor layer.

5. The array substrate of claim 1, wherein the first region of the oxide semiconductor layer is isolated from the second region of the oxide semiconductor layer.

6. The array substrate of claim 1, wherein the dielectric layer between the first electrode plate and the second electrode plate comprises a passivation layer and/or an etch stop layer.

7. The array substrate of claim 1, wherein the material for the oxide semiconductor layer is indium gallium zinc oxide, indium zinc oxide, indium tin oxide or indium gallium tin oxide.

8. The array substrate of claim 6, wherein
the etch stop layer and the passivation layer are each of transparent single layer or composite layers structure formed of any one or more selected from oxide of silicon, nitride of silicon, oxide of hafnium, oxynitride of silicon, or oxide of aluminum.

9. The array substrate of claim 1, the dielectric layer between the first electrode plates and the second electrode plates comprises an etch stop layer and a gate insulating layer.

10. A display device comprising the array substrate of claim 1.

11. A manufacturing method of an array substrate comprising: forming an oxide semiconductor layer, forming a pixel electrode pattern and forming a dielectric layer between the oxide semiconductor layer and the pixel electrode pattern, wherein the forming the oxide semiconductor layer comprises:
depositing an oxide film and forming a pattern including a first region of the oxide semiconductor layer and a second region of the oxide semiconductor layer by a patterning process, wherein the pixel electrode and the second region of the oxide semiconductor layer are overlapped so as to form a storage capacitor, the second region of the oxide semiconductor layer constitutes a first electrode plate of the storage capacitor, the pixel electrode corresponding to the second region of the oxide active layer constitutes a second electrode plate of the storage capacitor, and the dielectric layer between the first electrode plates and the second electrode plates constitutes a dielectric of the storage capacitor.

12. The manufacturing method of the array substrate of claim 11, wherein a pattern including the first electrode plate is formed by performing a hydrogen plasma process for the second region of the oxide semiconductor layer so that the first electrode plate has a resistivity smaller than 5×10′³Ω.cm.

13. The manufacturing method of the array substrate of claim 12, wherein the hydrogen plasma process has a processing time of 150 S, a processing power of 800˜2000 W, and a hydrogen plasma flow rate of 80 SCCM.

14. The manufacturing method of the array substrate of claim 1, wherein the dielectric layer comprises an etch stop layer and/or a passivation layer.

15. The array substrate of claim 2, wherein the first electrode plate has a resistivity smaller than 5×10⁻³Ω.cm.

16. The array substrate of claim 2, wherein the second region of the oxide semiconductor layer has a resistivity smaller than that of the first region of the oxide semiconductor layer.

17. The array substrate of claim 3, wherein the second region of the oxide semiconductor layer has a resistivity smaller than that of the first region of the oxide semiconductor layer.

18. The array substrate of claim 2, wherein the first region of the oxide semiconductor layer is isolated from the second region of the oxide semiconductor layer.

19. The array substrate of claim 3, wherein the first region of the oxide semiconductor layer is isolated from the second region of the oxide semiconductor layer.

20. The array substrate of claim 4, wherein the first region of the oxide semiconductor layer is isolated from the second region of the oxide semiconductor layer.
